(19) United States
(12) Patent Application Publication
(10) Pub. No.: US 2006/0227524 A1
(43) Pub. Date: Oct. 12, 2006

(54) Double capacity memory card package

(76) Inventor: Sheng-chih Hsu, Taipei (TW)

Correspondence Address: LIN & ASSOCIATES INTELLECTUAL PROPERTY, P.O. BOX 2339, SARATOGA, CA, 95070-0339, US

(21) Appl. No.: 11/100,961

(22) Filed: Apr. 6, 2005

(51) Int. Cl. H05K 7/14

(52) U.S. Cl. 361/796; 361/803; 361/804

(57) ABSTRACT

A double capacity memory card package includes two substrates each having a memory IC, a micro-controller and a series of connection terminals installed thereon. The two substrates, overlapping each other, are symmetrically held by means of a support frame around the peripheral edges, so that all memory ICs and micro-controllers are disposed on the inner surfaces of the memory card package, and all connection terminals are provided on exposed surfaces and toward opposite ends of the memory card. These two substrates can be either electrically connected to form an integrated memory to allow the user to access the memory without having to flip the memory card forward or backward, or individually detached, depending on the memory requirements for different applications.

### BACKGROUND OF THE INVENTION

1. Field of the Invention

The present invention relates to a double capacity memory card package, and in particular to a uniquely designed memory card package using two layers of circuit board that can provide twice the amount of memory as compared with the conventional memory card.

2. The Related Art

The memory cards are now used in most video and audio applications. A memory card is convenient to use and has a small form factor, but the memory card can provide large data storage capacity. With a card reader, large amounts of data can be accessed in a brief of time, thus making it suitable for storing audio and video images that are used by video games or portable digital devices.

A conventional memory card shown in FIG. 1 includes a plastic shell A formed like a flatbed container having the mouth or upper side open, and a plastic board embedded with a circuit board B is placed over the mouth. The circuit board B has a micro chip, a memory IC and related circuitry installed on one side, and a series of connection terminals C (also known as the golden fingers) provided on the opposite side or exposed surface of the plastic board. A memory card is thus formed with exposed connection terminals for insertion into the card slot of a card reader, so that the data stored in the memory card can be easily accessed by the computer application or gaming device.

With regard to the manner of operation, the side of the memory card exposed with connection terminals is first inserted into the card slot of a card reader. Once the power of the card reader is turned on, the card reader is electrically connected to the internal circuitry of the card reader to allow memory read/write operation to be performed on the memory card.

However, the conventional memory card usually contains one circuit board. Using an analogy for the present illustration, the memory installed on the circuit board can only be viewed as one hard disk unit. Some applications may need the capacity of two hard disks to run properly. For applications such as video and audio games, the user may need two memory cards and two card readers at the same time in order to satisfy the memory requirements, which is obviously not a good solution for the user.

### SUMMARY OF THE INVENTION

The primary objective of the present invention is to provide a double capacity memory card package that incorporates two substrates each embedded with a circuit board, on which a memory IC, a micro-controller and a series of connection terminals are installed.

The secondary objective of the invention is to provide a double capacity memory card package that includes a support frame provided around the peripheral edges of the substrates to hold the two substrates in symmetrically overlapping position, whereby all memory ICs and micro-controllers are disposed on the inner surfaces thereof, and all connection terminals are provided on the outer surfaces and toward opposite ends of the memory card. This design allows the user to insert the memory card package forward or backward without any problem.

The tertiary objective of the invention is to provide a double capacity memory card package that further includes two beveled cuts formed on diagonal corners of the two substrates, which are designed to prevent card insertion in the wrong direction.

In accordance with one aspect of the invention, the structure of a double capacity memory card package includes a first and second substrates each having a memory IC, a micro-controller and a series of connection terminals installed thereon, and a card holder that has the first and second substrates held in symmetrically overlapping position, so that the connection terminals are provided on exposed surfaces, thus forming a double capacity memory card package.

In accordance with another aspect of the invention, the memory card package has two beveled cut on diagonal corners, so the proper operation procedure is to use the side with the beveled cut on the right hand side and facing the card slot to be inserted, that means the memory card package may be inserted using either one of the two ends as long as the bevel cut is on the right hand side and lined up with the connection terminals, which are designed to prevent card insertion with wrong directions.

In accordance with still another aspect of the invention, the first and second substrates can be electrically connected to form an integrated memory pool on the card, or detached from each other, depending on the memory requirements for different applications.

The present invention will become more obvious from the following description when taken in connection with the accompanying drawings, which show, for purposes of illustration only, a preferred embodiment in accordance with the present invention.

### BRIEF DESCRIPTION OF THE DRAWINGS

FIG. 1 is a sectional view of the conventional memory card;

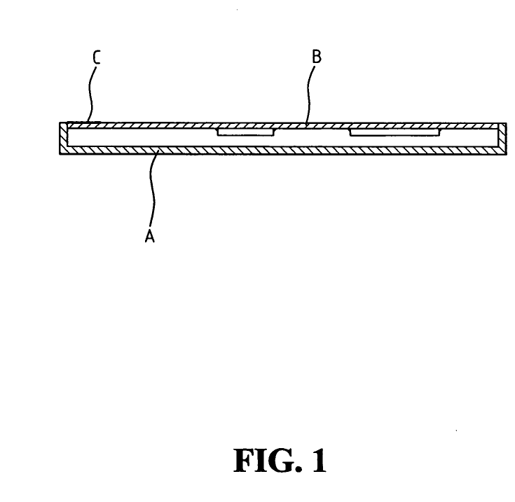

FIG. 2 is an exploded view of the structure of the memory card package according to the present invention;

FIG. 3 is a perspective view of an assembled memory card package;

FIG. 4 is a sectional view of the structure of one embodiment of the invention; and

FIG. 5 is a sectional view of the structure of another embodiment of the invention.

### DETAILED DESCRIPTION OF THE PREFERRED EMBODIMENT

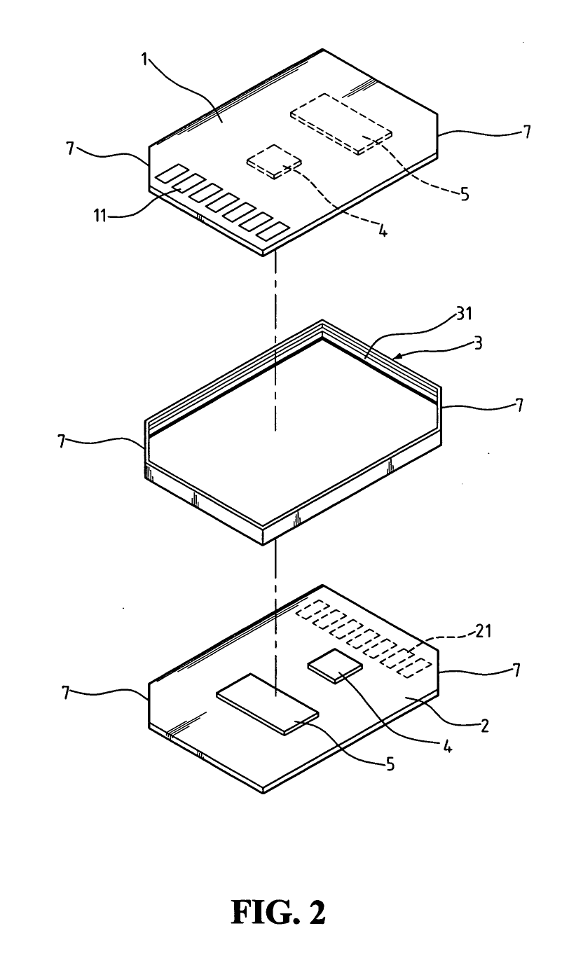

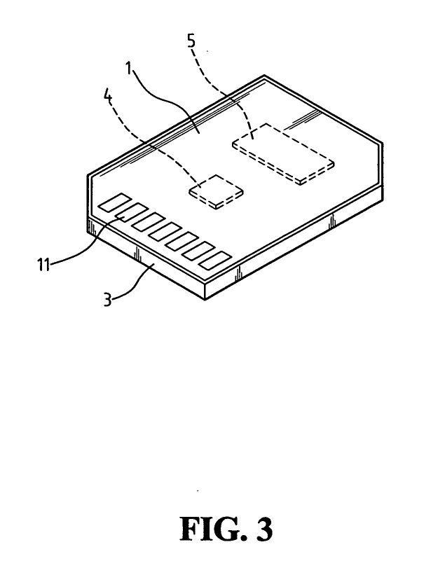

With reference to the drawings and in particular to FIGS. 2 and 3, a double capacity memory card package according to one preferred embodiment of the present invention comprises a first substrate 1, a second substrate 2 and a card holder 3, wherein each substrate is embedded with a circuit board, on which a micro-controller 4, a memory IC 5 and related circuitry are installed. The card holder 3 is used to hold the two substrates 1, 2 in symmetrically overlapping position around the peripheral edges of the substrates 1, 2, preferably be able to seal off the internal space, so that the first and second substrates 1, 2 are completely surrounded by the card holder 3, and the connection terminals 11, 12 of the first and second substrates 1, 2 are provided on exposed surfaces, which are also the smooth surfaces, and toward opposite ends of the memory card.

The card holder 3 further provides a rib 31 along the center line thereof to allow the two substrates 1, 2 to be placed onto the card holder 3 with a predetermined gap in between, so that the two substrates 1, 2 may be fixed either using adhesive that is coated on the adjoining surfaces or using bolts to fasten the two substrates 1, 2, so that the first and second substrates 1, 2 are positioned symmetrically and overlapping each other.

The memory card package has two beveled cuts 7 on diagonal corners. The proper procedure is to use one side with the beveled cut on the right side and facing the card slot to be inserted, that is also the end with the connection terminals and the beveled cut almost lined up on a straight line. This means the memory card package may be inserted using both ends as long as the bevel cut is on the right hand side and facing the card slot, which are designed to prevent erroneous insertion of the card in the wrong directions.

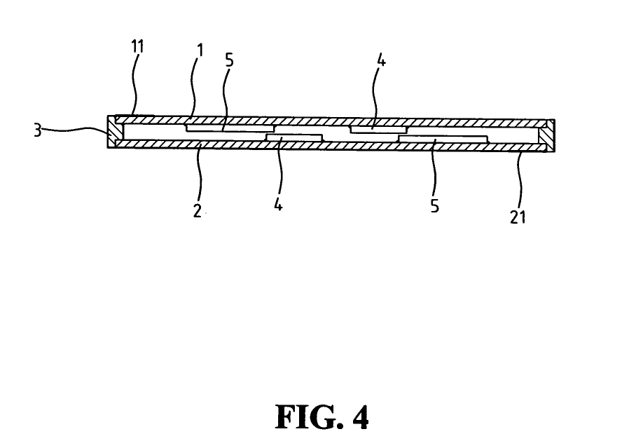

In one embodiment of the invention, the two substrates 1, 2 embedded with circuit board are detached from each other as shown in FIG. 4, so the memory on both sides thereof may be viewed as two hard disk units, only for the sake of the present illustration. If the memory card is inserted with the front side facing up, that is equivalent to using the first hard disk. If the memory card is then pulled out and re-inserted with the back side facing up, that is equivalent to switching from the first hard disk to the second hard disk. This is the simplest way to manage two memory units being bundled into one memory card package.

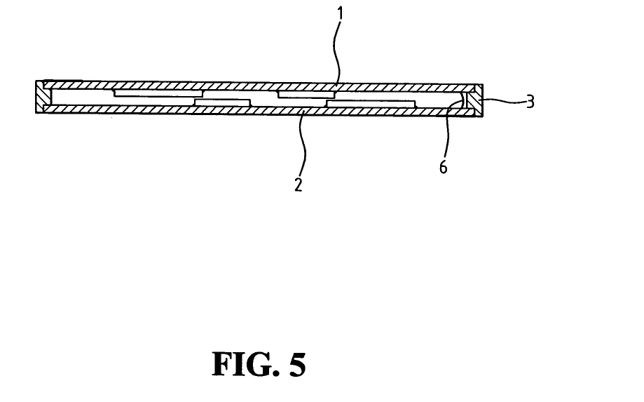

Alternatively, according to another embodiment of the invention shown in FIG. 5, the substrates 1, 2 in the memory card package are interconnected by lead wires 6, so that the memory ICs 5 and the micro-controllers 5 on both circuit boards are integrated into a unitary memory pool, whereby the user is able to make use of the memory capacity existing on two memory ICs without having to flip the memory card forward or backward, as the total memory capacity is the summation of the two memory ICs 5.

It is to be appreciated that whether or not the two circuit boards shall be interconnected is largely dependent on the market demand and the memory requirements for different applications, therefore changes may be made in the related circuitry by one with ordinary skill in the art within the scope of the present invention.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A double capacity memory card package, comprising:
a first substrate having a memory IC and a micro-controller installed on one side and a series of connection terminals on another side;
a second substrate having a memory IC and a micro-controller installed on one side and a series of connection terminals on another side; and
a card holder which is used to join the two substrates in symmetrically overlapping position, so that the connection terminals are provided on exposed surfaces and toward opposite ends of the memory card.

2. The double capacity memory card package as claimed in claim 1, wherein the first and second substrates are electrically connected.

3. The double capacity memory card package as claimed in claim 1, wherein the card holder is actually a support frame that is mounted around the peripheral edges of the first and second substrates to allow the two substrates to be held in symmetrically overlapping position and the connection terminals to be provided on exposed surfaces of the memory card package.

4. The double capacity memory card package as claimed in claim 1, wherein the two substrates each has a series of connection terminals on exposed surface, so that the connection terminals of the two substrates are alternately provided on opposite ends of the memory card package.

5. The double capacity memory card package as claimed in claim 4, wherein the first and second substrates each has two beveled cuts formed on a pair of diagonal corners to indicate the direction of card insertion.

6. The double capacity memory card package as claimed in claim 3, wherein the two substrates each has a series of connection terminals on exposed surface, so that the connection terminals of the two substrates are alternately provided on opposite ends of the memory card package.

7. The double capacity memory card package as claimed in claim 6, wherein the first and second substrates each has two beveled cuts formed on a pair of diagonal corners to indicate the direction of card insertion.
